(19) United States
(12) Patent Application Publication
(10) Pub. No.: US 2026/0039310 A1
(43) Pub. Date: Feb. 5, 2026

(54) DELTA-SIGMA ANALOG-TO-DIGITAL CONVERTER AND BATTERY IMPEDANCE MEASUREMENT DEVICE

(71) Applicant: DENSO CORPORATION, Kariya-city (JP)

(72) Inventor: Kazuo MATSUKAWA, Kariya-city (JP)

(21) Appl. No.: 19/351,550

(22) Filed: Oct. 7, 2025

Related U.S. Application Data
(63) Continuation of application No. PCT/JP2024/010289, filed on Mar. 15, 2024.

(30) Foreign Application Priority Data
Apr. 13, 2023 (JP) 2023-065650

(51) Int. Cl. H03M 3/00; G01R 31/389

(52) U.S. Cl. CPC H03M 3/496; G01R 31/389; H03M 3/464

(57) ABSTRACT

A delta-sigma analog-to-digital converter includes a first integrator, an input chopping switch, an output chopping switch, a second integrator, a sampling capacitive element, an addition capacitive element, an odd-numbered subtraction capacitive element, an even-numbered subtraction capacitive element. The first integrator includes a differential structure, and samples an input voltage according to a first clock signal. The input chopping switch performs a chopping operation by alternately switching a connection to a positive input terminal and a negative input terminal of the first integrator according to a second clock signal being an inverted phase of the first clock signal. The output chopping switch performs a chopping operation by alternately switching a connection to a positive output terminal and a negative output terminal of the first integrator according to the second clock signal. The second integrator includes a differential structure and located after the first integrator.

### CROSS REFERENCE TO RELATED APPLICATIONS

The present application is a continuation application of International Patent Application No. PCT/JP2024/010289 filed on Mar. 15, 2024, which designated the U.S. and claims the benefit of priority from Japanese Patent Application No. 2023-065650 filed on Apr. 13, 2023. The entire disclosures of all of the above applications are incorporated herein by reference.

### TECHNICAL FIELD

The present disclosure relates to a delta-sigma analog-to-digital (A/D) converter and a battery impedance measurement device using the A/D converter.

### BACKGROUND

A delta-sigma analog-to-digital (A/D) converter may have the architecture of cascaded-of-integrator feedforward (CIFF).

### SUMMARY

The present disclosure describes a delta-sigma analog-to-digital converter that includes first and second integrators, and further describes a battery impedance measurement device that includes the delta-sigma analog-to-digital converter.

### BRIEF DESCRIPTION OF DRAWINGS

Objects, features and advantages of the present disclosure will become more apparent from the following detailed description made with reference to the accompanying drawings. In the drawings:

FIG. 1 is a diagram showing a configuration of a delta-sigma A/D converter in a first embodiment;

FIG. 2 is a functional block diagram showing a second-order delta-sigma A/D converter including a general adder circuit;

FIG. 3 is a functional block diagram showing a configuration equivalent to that of FIG. 2;

FIG. 4 is a diagram showing waveforms of each clock signal that controls a delta-sigma A/D converter;

FIG. 5 is a diagram (part 1) for explaining the operation of a first integrator;

FIG. 6 is a diagram (part 2) for explaining the operation of the first integrator;

FIG. 7 is a diagram (part 3) for explaining the operation of the first integrator;

FIG. 8 is a diagram (part 1) for explaining the operation of the second integrator;

FIG. 9 is a diagram (part 2) for explaining the operation of the second integrator;

FIG. 10 is a diagram (part 3) for explaining the operation of the second integrator;

FIG. 11 is a diagram (part 4) for explaining the operation of the second integrator;

FIG. 12 is a diagram showing an image of an operation performed by a pseudo-addition circuit;

FIG. 13 is a diagram showing a configuration of a delta-sigma A/D converter in a second embodiment;

FIG. 14 is a functional block diagram showing a second-order delta-sigma A/D converter including a general adder circuit;

FIG. 15 is a functional block diagram showing a configuration equivalent to that of FIG. 14; and

FIG. 16 is a diagram showing a configuration of a battery impedance measurement device in a third embodiment.

### DETAILED DESCRIPTION

A CIFF A/D converter may include first and second integrators and has a forward path for performing addition. However, the value in the forward addition path may not be the value at the same timing of the first integrator. Also, sampling in the second integrator occurs in a phase as phase (1) and sampling in the forward addition path occurs in another phase as phase (2). There may be no issue with the first integrator since it has the same value in phases (1) and (2). However, if chopping is performed on the input side of the first integrator to reduce noise, it may not be possible to have the values at the same timing. In addition, an adder using an operational amplifier may be provided, but in that case, an increase in circuit area and current consumption may become an issue. In the present disclosure, the adder may also be referred to as a summer.

According to an aspect of the present disclosure, a delta-sigma analog-to-digital converter includes a first integrator, an input chopping switch, an output chopping switch, a second integrator, sampling capacitive elements, addition capacitive elements, odd-numbered subtraction capacitive elements, and even-numbered subtraction capacitive elements. The first integrator includes a differential structure, and samples an input voltage according to a first clock signal. The input chopping switch performs a chopping operation in which electrical connections to a positive input terminal and a negative input terminal of the first integrator are alternatively switched according to a second clock signal being an inverted phase of the first clock signal. The output chopping switch performs a chopping operation by alternately switching a connection to a positive output terminal and a negative output terminal of the first integrator according to the second clock signal. The second integrator includes a differential structure and located after the first integrator. The sampling capacitive elements and the addition capacitive elements are located at an input of the second integrator on both sides of the differential structure of the second integrator. The odd-numbered subtraction capacitive elements are located at the input of the second integrator on both sides of the differential structure of the second integrator. The even-numbered subtraction capacitive elements are located at the input of the second integrator on both sides of the differential structure of the second integrator. A sampling capacitive element and an addition capacitive element on one of the sides of the differential structure of the second integrator are configured to sample a first output signal of the first integrator according to the second clock signal. A sampling capacitive element and an addition capacitive element on an other of the sides of the differential structure of the second integrator are configured to sample a second output signal of the first integrator according to the second clock signal. An odd-numbered subtraction capacitive element on the one of the sides of the differential structure of the second integrator is configured to sample the second output signal according to an odd-numbered clock of the second clock signal. An odd-numbered subtraction capacitive element on the other of the sides of the differential structure of the second integrator is configured to sample the first output signal according to the odd-numbered clock of the second clock signal. An even-numbered subtraction capacitive element on the one of the sides of the differential structure of the second integrator is configured to sample the second output signal according to an even-numbered clock of the second clock signal. An even-numbered subtraction capacitive element on the other of the sides of the differential structure of the second integrator is configured to sample the first output signal according to the even-numbered clock of the second clock signal. The second integrator integrates an electric charge sampled at the sampling capacitive elements, the addition capacitive elements, and the odd-numbered subtraction capacitive elements according to an odd-numbered clock of the first clock signal on both sides of the differential structure of the second integrator, and integrate an electric charge sampled at the sampling capacitive elements, the addition capacitive elements, and the even-numbered subtraction capacitive elements according to an even-numbered clock of the first clock signal on both sides of the differential structure of the second integrator.

Accordingly, it is possible to add the charge sampled from the output signal of the first integrator by the above-mentioned operation at the input side of the second integrator as a value at the same timing as the first integrator, without having to provide an adder circuit equipped with an operational amplifier or the like that generates excess current consumption.

Furthermore, the battery impedance measurement device according to the present disclosure includes the delta-sigma A/D converter, and measures the terminal voltage of the secondary battery and the current flowing through the secondary battery using this delta-sigma A/D converter. Based on the measured terminal voltage and current, the impedance of the secondary battery is measured. Generally, when measuring the impedance of a battery, it is necessary to perform the measurement in a low frequency band of about 0.1 Hz to 1 kHz, and the A/D converter is also required to have low noise characteristics in the same frequency band. When the A/D converter includes an operational amplifier configured with, for example, a MOSFET, the level of low-frequency noise caused by flicker noise is high, and chopping techniques are used to reduce this noise. Therefore, it is possible to apply the delta-sigma A/D converter according to the present disclosure to a device for measuring the impedance of a battery.

### First Embodiment

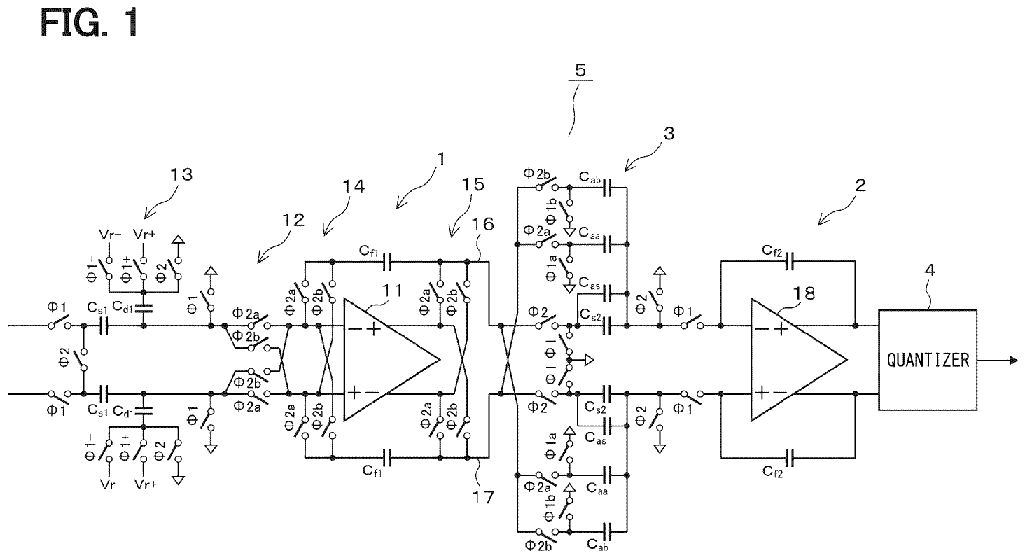

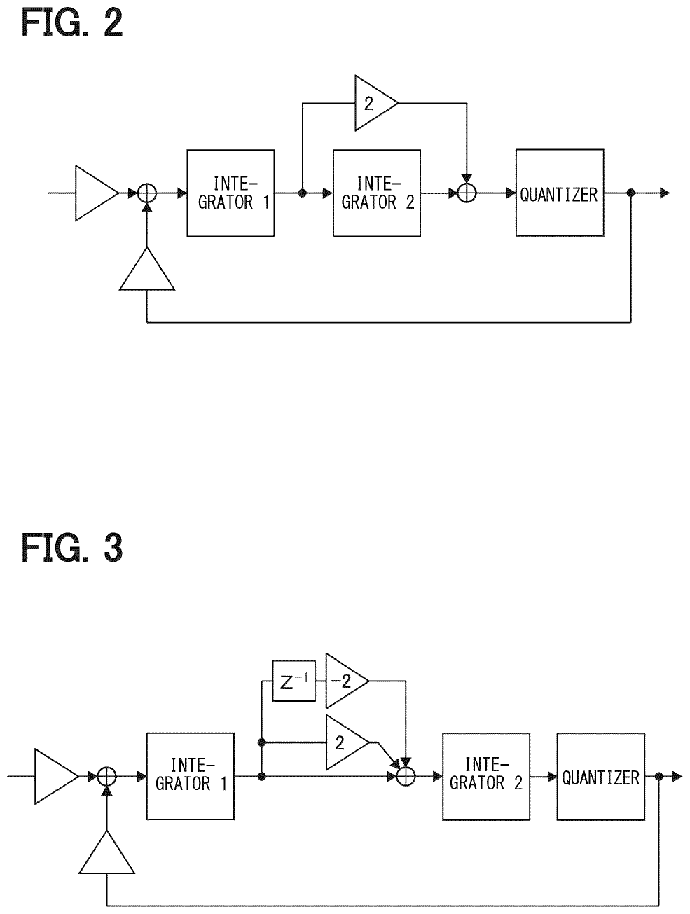

A CIFF type second-order delta-sigma A/D converter according to the present embodiment shown in FIG. 1 is derived based on the block configuration of the A/D converter shown in FIG. 2. In FIG. 2, a first integrator and a second integrator are connected in series, and the output of the first integrator is doubled and added to the output of the second integrator by an adder. The result of the addition is provided to the quantizer. As shown in FIG. 3, it is equivalent to a configuration where the adder is placed on the input side of the second integrator, and the output of the first integrator is doubled and added to the same output that has been doubled negatively via a delay element.

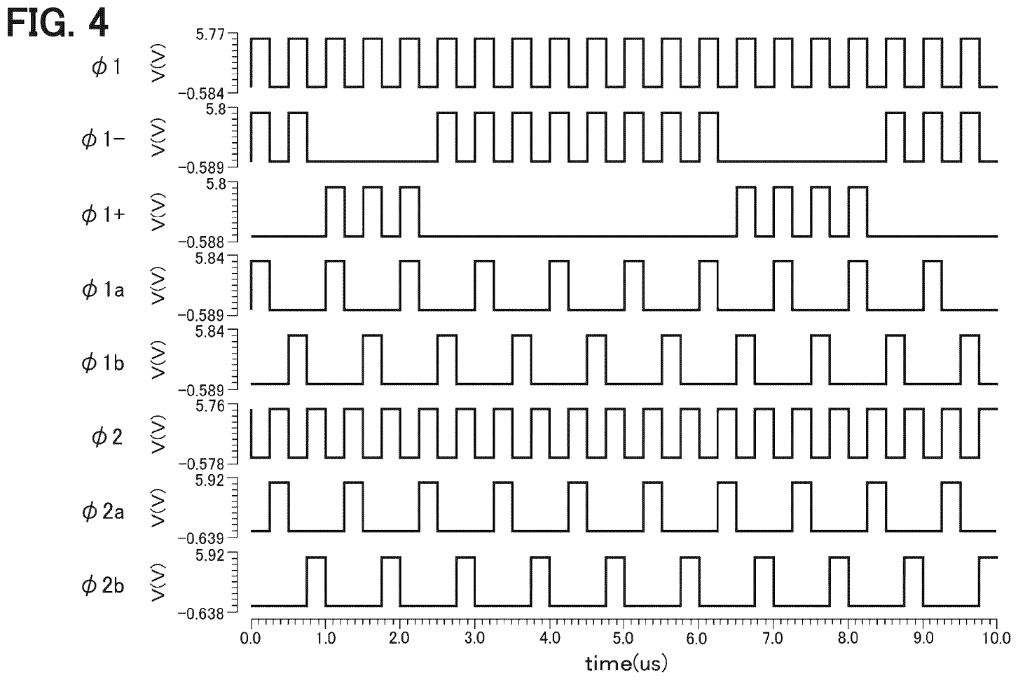

The delta-sigma A/D converter according to the present embodiment is implemented as a differential circuit based on the block configuration shown in FIG. 3. The delta-sigma A/D converter operates with eight types of clock signals shown in FIG. 4. φ1 denotes a master clock signal, and corresponds to a first clock signal. φ1+ denotes an output if the quantizer output is L. φ1—denotes an output if the quantizer output is H. φ1a denotes an odd-numbered clock of φ1. φ1b denotes an even-numbered clock of φ1. φ2 denotes an inverted phase clock signal of φ1, and corresponds to a second clock signal. φ2a denotes an odd-numbered clock of φ2. φ2b denotes an even-numbered clock of φ2. The odd and even numbers are relative numbers when the left end of the clock signal φ1 shown in FIG. 4 is taken as “1”, for example. Moreover, with regard to the switches described below, those that are turned on and off by the above clock signals are indicated with the type of clock.

A series circuit of a switch φ1, a capacitor Cs1 serving as a sampling capacitive element, and a first chopping switch 12 is connected to each input terminal of an operational amplifier 11 included in the first integrator 1. The first chopping switch 12 includes two switches φ2a and two switches φ2b, where the two switches φ2a are connected straight to each input terminal, and the two switches φ2b are connected so as to cross the positive input terminal and the negative input terminal.

A common connection node between the capacitor Cs1 and the first chopping switch 12 is connected to one end of a capacitor Cd1 and one end of the switch φ1 which is included in the D/A converter 13. The other end of the capacitor Cd1 is commonly connected to one end of switches φ1-, φ1-, and φ2, and the other end of these switches and the switch φ1 are connected to reference voltages Vr−, Vr+, and a standard voltage, respectively. The reference voltage is, for example, an analog ground level, and the magnitude relationship between these voltages is set to (Vr−<reference voltage<Vr+). The first and second chopping switches 12 and 14 correspond to input side chopping switches that may also be simply referred to as an input chopping switches.

A series circuit of the second chopping switch 14, a capacitor Cf1, and a third chopping switch 15 is connected between the input side and the output side of the operational amplifier 11. Like the chopping switch 12, each of these chopping switches 14 and 15 includes two switches φ2a and two switches φ2b. The switch φ2a is connected straight between the negative input terminal and the positive output terminal, and between the positive input terminal and the negative output terminal, and the switch φ2b is connected crosswise so that the polarity of the input side and the output side is reversed. The third chopping switch 15 corresponds to an output side chopping switch. Either the positive or negative output signal of the first integrator 1 corresponds to a first output signal, and the other corresponds to a second output signal.

A pseudo-addition circuit 3 is disposed between the first integrator 1 and the second integrator 2. Between the output line 16 of the first integrator 1 and the negative input terminal of the operational amplifier 18 that is included in the second integrator 2, there are connected a switch φ2, a parallel circuit of capacitors Cs2 and Cas, and a series circuit of a switch φ1, which are included at one polarity side of the pseudo-addition circuit 3. The configuration between the output line 17 of the first integrator 1 and the positive input terminal of the operational amplifier 18 is also similar.

A series circuit of a switch φ2a and a capacitor Caa, and a series circuit of a switch φ2b and a capacitor Cab are connected between the output line 17 and a common connection node between the capacitors Cs2 and Cas and the switch φ1. Switches φ1a and φ1 b are connected between the common connection node of each series circuit and a reference voltage. The configuration on the side connected to the output line 16 is similar. A switch φ2 is connected between a common connection node of the capacitors Cs2 and Cas and the switch φ1 and a reference voltage. The capacitances of the capacitors Cas, Caa, and Cab are set to be equal. The capacitors Cas, Caa and Cab correspond to capacitive elements for addition, odd-number subtraction and even-number operation, respectively.

A capacitor Cf2 is connected between the input terminal and the output terminal of an operational amplifier 18 that is included in the second integrator 2, and the output terminal is connected to the input terminal of a quantizer 4. The pseudo-addition circuit 3 performs addition with a gain of “2” as described below while utilizing the configuration of the second integrator 2. The above is included in the delta-sigma A/D converter 5.

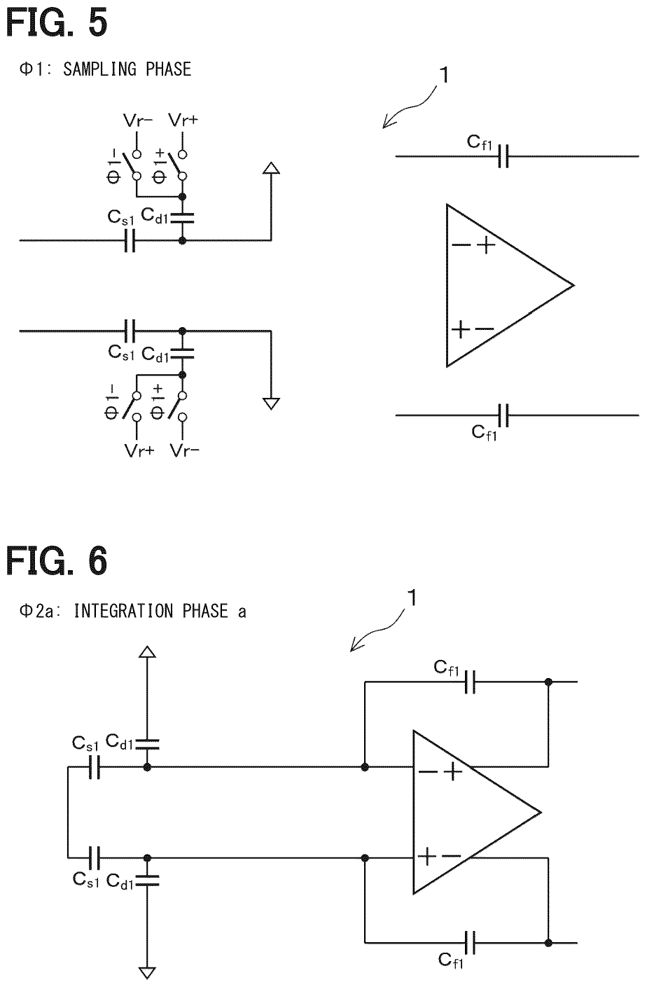

The following describes an operation in the present embodiment. First, the operation of the first integrator 1 will be described. In the following FIGS. 5 to 11, in order to make the operation easier to understand, illustrations of the individual switches are omitted where appropriate, and the switches that are turned on in accordance with the respective clocks are indicated by solid lines.

### (φ1: Sampling Phase)

In the sampling phase shown in FIG. 5, the capacitor Cs1 is charged by the input voltage and sampling is performed.

### (φ2a: Integration Phase a)

In the integration phase a shown in FIG. 6, the charges of the capacitors Cs1 and Cd1 are integrated into the capacitor Cf1.

### (φ2b: Integration Phase b)

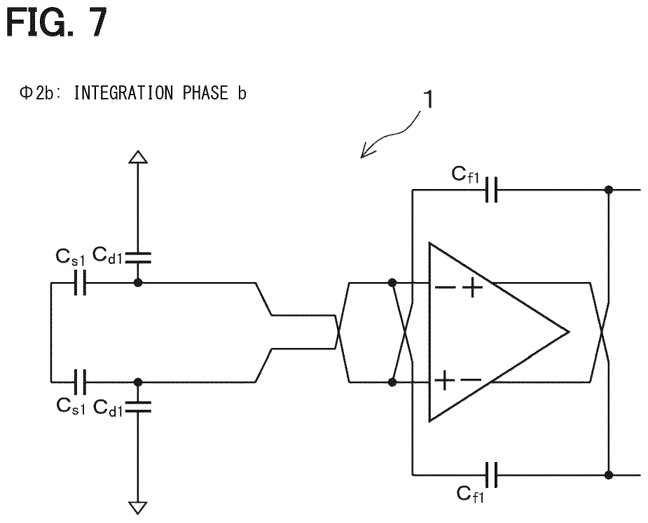

In the integration phase b shown in FIG. 7, while the polarities of the input and output terminals of the operational amplifier 11 are switched by the chopping switches 12, 14, and 15, the charges of the capacitors Cs1 and Cd1 are integrated in the capacitor Cf1.

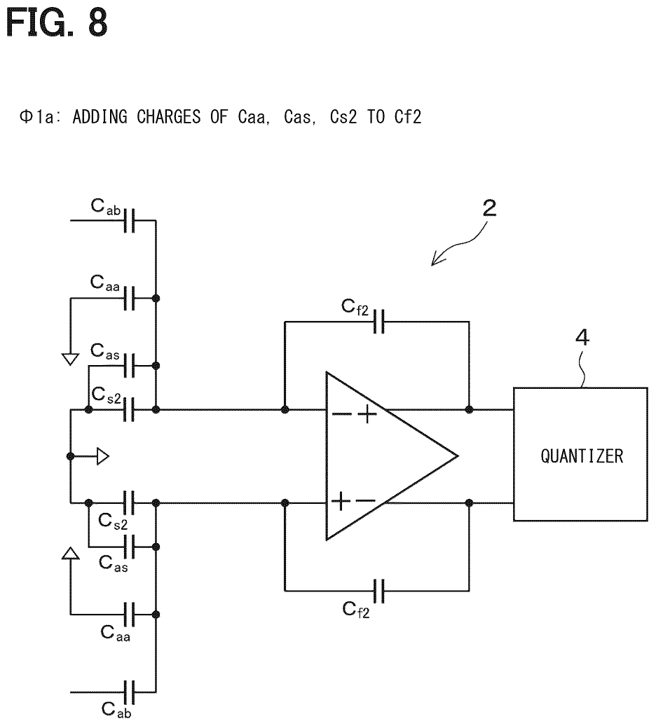

Next, the operation of the pseudo-addition circuit 3 and the second integrator 2 will be described. In the operation of the second integrator 2 shown in FIGS. 8 to 11, the clock is generated cyclically as φ1a→φ2a→φ1b→φ2b→φ1a→ . . . , so that four phases are repeatedly executed. Further, the explanation involving positive and negative polarities will be given with respect to one side of the differential structure, that is, the upper side in the drawing.

### (φ1a: First Phase)

In the first phase shown in FIG. 8, the charges of capacitors Caa, Cas and Cs2 are added to the capacitor Cf2.

### (φ2a: Second Phase)

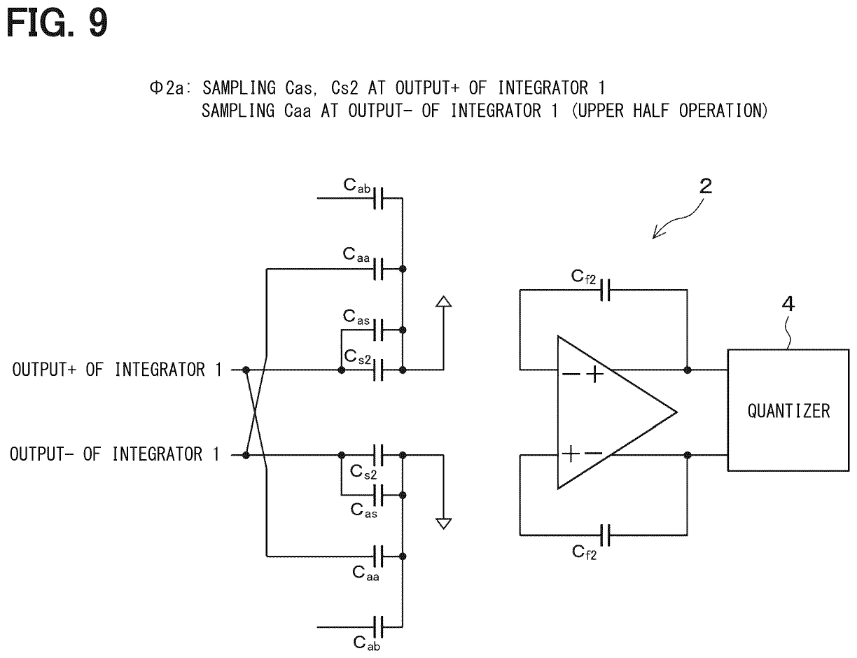

In the second phase shown in FIG. 9, the capacitors Cas and Cs2 are charged with the positive output of the first integrator 1 and sampled, and the capacitor Caa is charged with the negative output of the first integrator 1 and sampled.

### (φ1b: Third Phase)

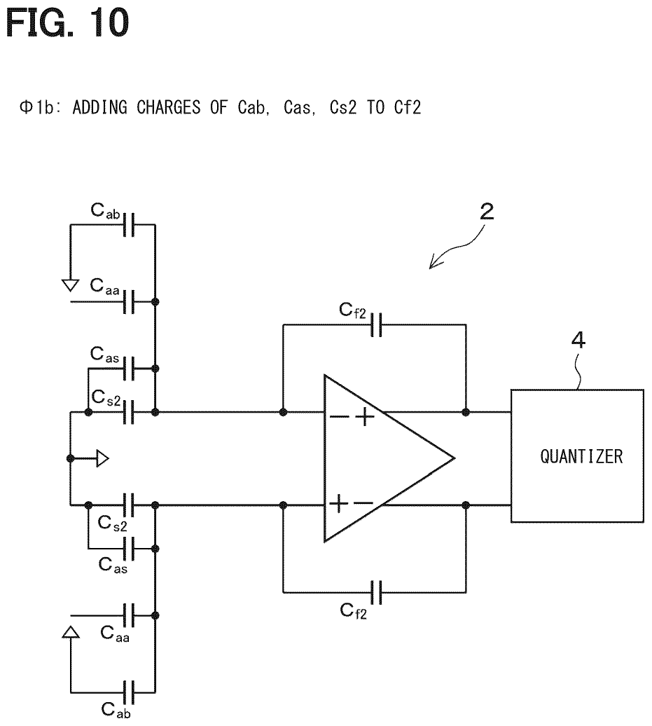

In the third phase shown in FIG. 10, the charges of capacitors Cab, Cas and Cs2 are added to the capacitor Cf2.

### (φ2b: Fourth Phase)

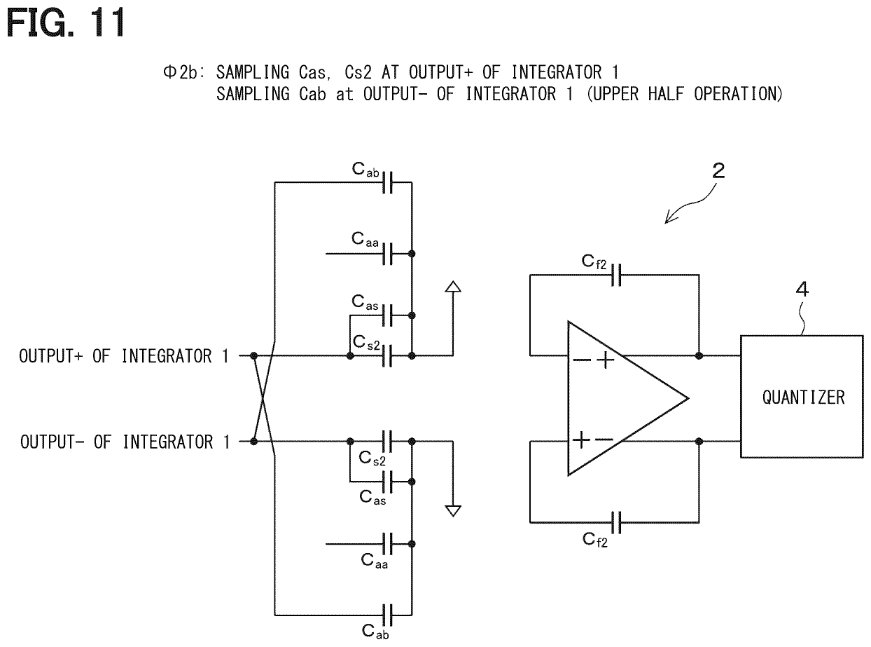

In the fourth phase shown in FIG. 11, the capacitors Cas and Cs2 are charged with the positive output of the first integrator 1 and sampled, and the capacitor Cab is charged with the negative output of the first integrator 1 and sampled.

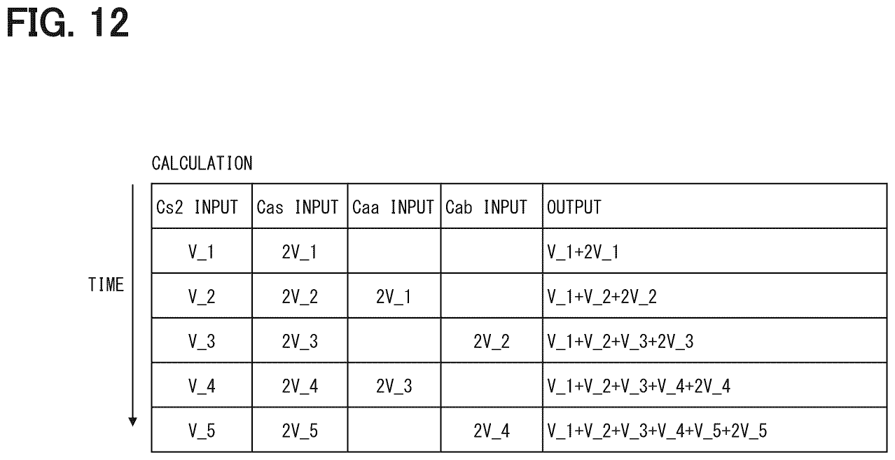

As a result of repeating the above operations, the time-series calculation image of the first and third phases becomes as shown in FIG. 12. The output of each addition result has double the value of the input at that time added to it, but at the timing of the next addition, the double value added previously is subtracted. In this manner, the input voltages are sequentially cumulatively added.

As described above, according to the present embodiment, in the delta-sigma A/D converter 5, the first integrator 1 samples the input voltage in accordance with the first clock signal φ1. The first to third chopping switches 12, 14 and 15 perform a chopping operation of alternately switching the positive and negative input terminals and the positive and negative output terminals of the first integrator 1 in accordance with the second clock signal φ2.

On the input side of the second integrator 2 and on one side of the differential structure, the sampling capacitive element Cs2 and the addition capacitive element Cas sample the first output signal of the first integrator 1 in accordance with the second clock signal φ2. The odd-numbered subtraction capacitive element Caa1 samples the second output signal of the first integrator in accordance with the odd-numbered clock φ2a of the second clock signal, and the even-numbered subtraction capacitive element Cab samples the second output signal in accordance with the even-numbered clock φ2b of the second clock signal.

In accordance with the odd-numbered clock φ1a of the first clock signal, the sampled charges are integrated by the sampling capacitor Cs2, the addition capacitor Cas, and the odd subtraction capacitor Caa. In accordance with the even-numbered clock φ1b of the first clock signal, the sampled charges are integrated by the sampling capacitor Cs2, the addition capacitor Cas, and the even subtraction capacitor Cab. The other side of the differential structure operates in a similar manner to the first side, with the first and second output signals swapped.

With this configuration, it is possible to add the charge sampled based on the output signal of the first integrator 1 by the operation of the pseudo-addition circuit 3 arranged on the input side of the second integrator 2 as a value at the same timing as the first integrator 1, without having an adder circuit equipped with an operational amplifier or the like that generates excess current consumption.

### Second Embodiment

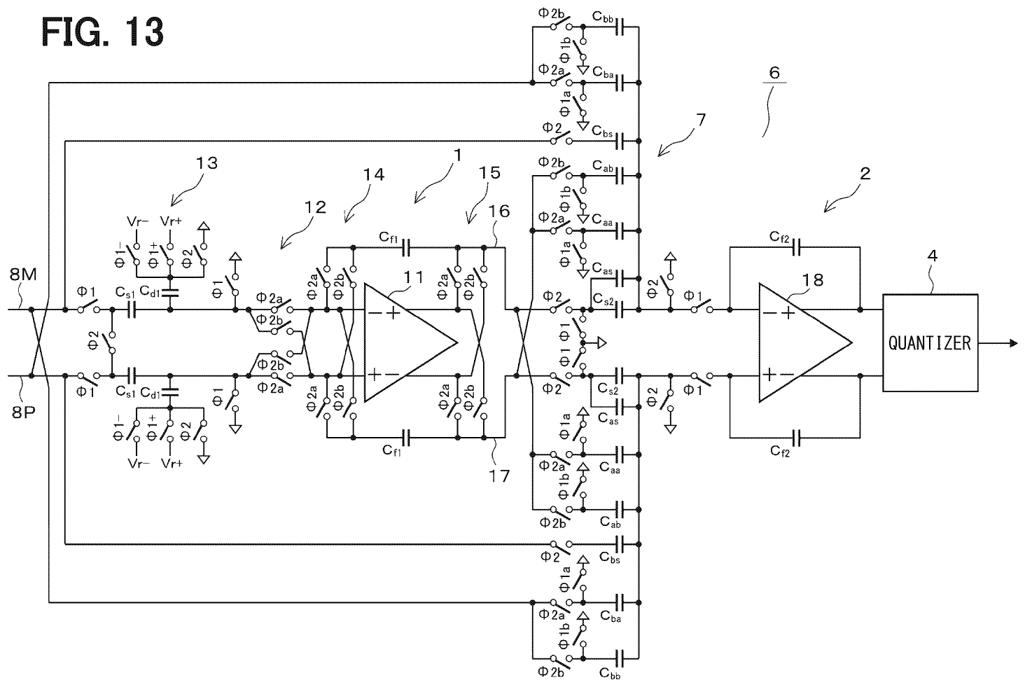

Hereinafter, the same components as those of the first embodiment are denoted by the same reference numerals, and descriptions of the same components will be omitted, and different portions will be described. A delta-sigma A/D converter 6 according to the second embodiment shown in FIG. 13 has a configuration in which the pseudo-addition circuit 3 of the delta-sigma A/D converter 5 according to the first embodiment is replaced with a pseudo-addition circuit 7. The delta-sigma A/D converter 6 has a forward path in a pseudo-addition circuit 7 for adding the voltages provided to the first integrator 1.

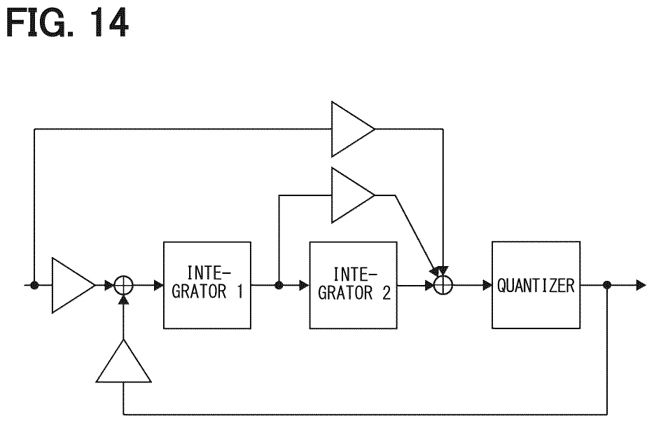

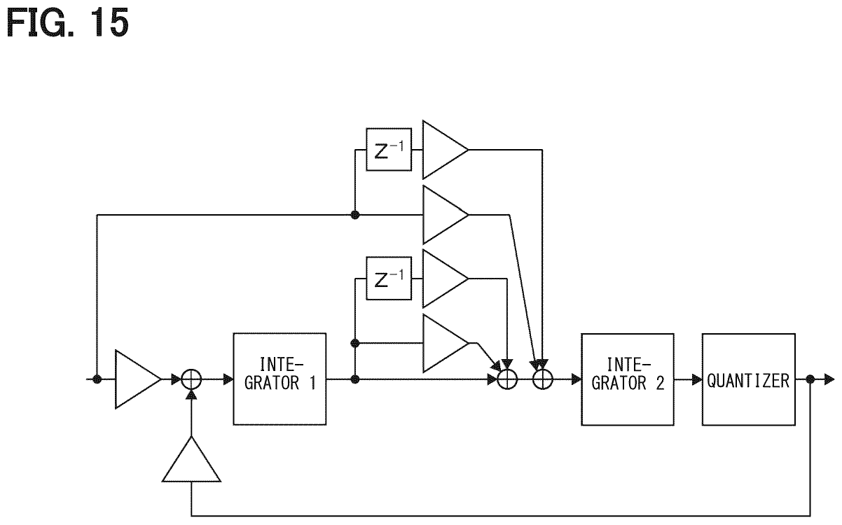

Assuming the block configuration shown in FIG. 14, similar to FIGS. 2 and 3 of the first embodiment, it becomes equivalent to the block configuration shown in FIG. 15, and the circuit formed by differentiating the latter block configuration is the delta-sigma A/D converter 6. Referring to each input terminal of the delta-sigma A/D converter 6 as 8M and 8P respectively, the configuration on the upper side of the pseudo addition circuit 7 in the drawing will be explained below.

Between the input terminal 8M and the common connection node of the capacitors Cs2 to Cab, a series circuit of a switch φ2 and a capacitor Cbs, which is an addition capacitive element, is connected. In addition, between the input terminal 8P and the above-mentioned common connection node, a series circuit of a switch φ2a and a capacitor Cba, which is a capacitive element for odd-number subtraction, and a series circuit of a switch φ2b and a capacitor Cbb, which is a capacitive element for even-number subtraction, are connected in parallel. The switches φ1a and φ1b are connected between the common connection node of each series circuit and a reference voltage. In the configuration on the lower side of the drawing, the input terminals 8M and 8P are interchanged with those in the above configuration. The operation of the parts added to the pseudo adder circuit 7 is similar to that of the corresponding capacitive elements in the first embodiment.

### Third Embodiment

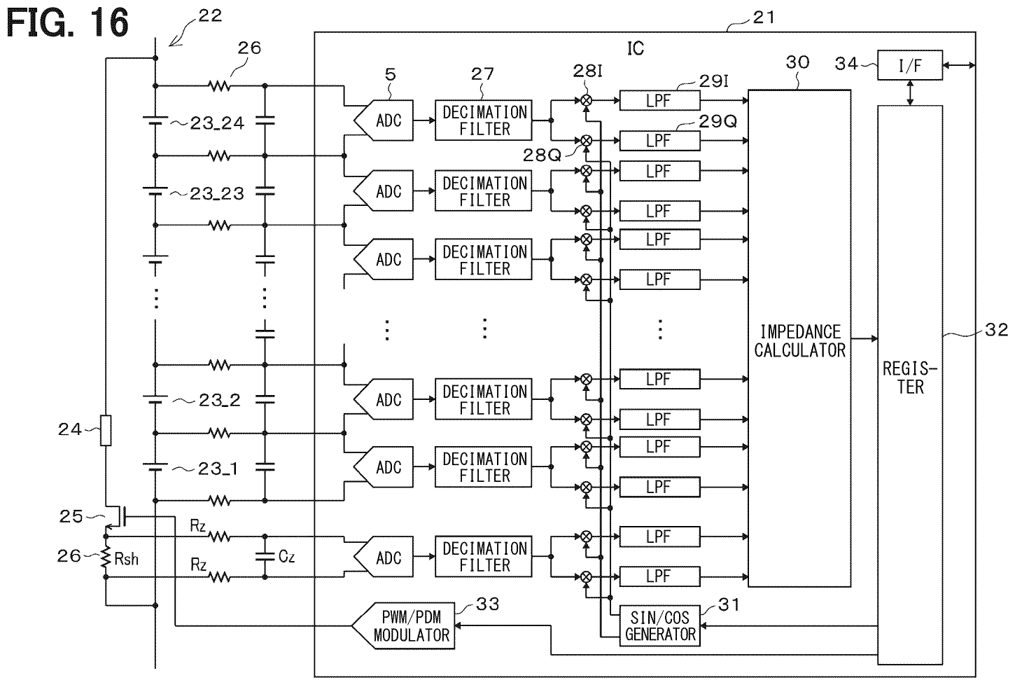

A third embodiment shown in FIG. 16 shows a configuration in which the delta-sigma A/D converter 5 according to the first embodiment is applied to a battery impedance measurement device 21 using a lock-in amplifier. Hereinafter, the battery impedance measurement device 21 is simply referred to as a measurement device 21. The measurement device 21 is an integrated circuit (IC), and measures the impedance of each of the twenty four unit cells 23_1 to 23_24 that are included in a battery pack 22. A series circuit including a load 24, an N-channel MOSFET 25, and a shunt resistor Rsh is connected in parallel to the battery pack 22.

An RC filter 26 is connected to each unit cell 23, which is a secondary battery, and both ends of the capacitor that is included in the RC filter 26 are connected to each input terminal of the delta-sigma A/D converter 5, indicated by “ADC” in the drawing. That is, the terminal voltage of the unit cell 23 is measured by the delta-sigma A/D converter 5 and processed by analog-to-digital conversion. The data output from the delta-sigma A/D converter 5 is input to the decimation filter 27, where the data is downsampled. The output of the decimation filter 27 is split into two branches and provided to an impedance calculation unit 30 via a multiplier 28I and an LPF 29I, and a multiplier 28Q and an LPF 29Q. The multipliers 28I and 28Q receive the SIN and COS signals generated by a SIN/COS generator 31 and perform orthogonal transformation.

Incidentally, a set of the A/D converter 5 to the LPF 29 is also provided for the shunt resistor Rsh, and each input terminal of the corresponding A/D converter 5 is connected to both ends of the shunt resistor Rsh via a resistive element Rz. In addition, a capacitor Cz is connected between the input terminals. A PWM (Pulse Width Modulation) signal or a PDM (Pulse Density Modulation) signal output from a PWM/PDM modulator 33 is applied to the gate of an FET 25. When the FET 25 is turned on, the A/D converter 5 detects a terminal voltage corresponding to a current flowing from the battery pack 22 through the load 24 to the shunt resistor Rsh.

The impedance calculation unit 30 receives each input, and outputs the calculated impedance of the unit cell 23 to a register 32. An interface 34 for communicating with the outside is connected to the register 32, and the impedance value data stored in the register 32 is transmitted to, for example, an external higher-level controller. By writing to the register 32 via the interface 34 from an external source, the frequency settings of the SIN/COS generator 31 and the modulation method in the PWM/PDM modulator 33 are set. Additionally, when the register 32 receives a measurement start command via the interface 34, the SIN/COS generator 31 begins operation, and consequently, the excitation signal modulated by the PWM/PDM modulator 33 is output.

Generally, when measuring the impedance of a battery, it is necessary to perform the measurement in a low frequency band of about 0.1 Hz to 1 kHz, and the A/D converter is also required to have low noise characteristics in the same frequency band. If the A/D converter includes an operational amplifier composed, for example, of MOSFETs, the level of low-frequency noise due to flicker noise is high. Since that noise can be reduced by performing chopping, the delta-sigma A/D converter 5 is suitable for the device 21 that measures the impedance of the unit cell 23.

### Other Embodiments

The present disclosure may be applied to devices other than battery impedance measurement devices.

Although having been described in accordance with examples, the present disclosure should not be limited to the examples and structures. The present disclosure encompasses various modifications and variations within the scope of equivalents. In addition, various combinations and forms, and further, other combinations and forms including only one element, or more or less than these elements are also within the scope and the scope of the present disclosure.

What is claimed is:

1. A delta-sigma analog-to-digital converter comprising:
a first integrator having a differential structure, the first integrator configured to sample an input voltage according to a first clock signal;
an input chopping switch configured to perform a chopping operation in which electrical connections to a positive input terminal and a negative input terminal of the first integrator are alternately switched according to a second clock signal being an inverted phase of the first clock signal;
an output chopping switch configured to perform a chopping operation by alternately switching a connection to a positive output terminal and a negative output terminal of the first integrator according to the second clock signal;
a second integrator including a differential structure and located after the first integrator;
sampling capacitive elements and addition capacitive elements located on both sides of the differential structure of the second integrator, a sampling capacitive element and an addition capacitive element located on one side of the differential structure being configured to sample a first output signal of the first integrator according to the second clock signal, a sampling capacitive element and an addition capacitive element on an other side of the differential structure of the second integrator being configured to sample a second output signal of the first integrator according to the second clock signal;
odd-numbered subtraction capacitive elements located on both sides of the differential structure of the second integrator, an odd-numbered subtraction capacitive element on the one of the sides of the differential structure of the second integrator being configured to sample the second output signal according to an odd-numbered clock of the second clock signal, an odd-numbered subtraction capacitive element on the other of the sides of the differential structure of the second integrator is configured to sample the first output signal according to the odd-numbered clock of the second clock signal; and
even-numbered subtraction capacitive elements located on both sides of the differential structure of the second integrator, an even-numbered subtraction capacitive element on the one of the sides of the differential structure of the second integrator being configured to sample the second output signal according to an even-numbered clock of the second clock signal, an even-numbered subtraction capacitive element on the other of the sides of the differential structure of the second integrator being configured to sample the first output signal according to the even-numbered clock of the second clock signal, wherein
the second integrator is configured to:
integrate an electric charge sampled at the sampling capacitive elements, the addition capacitive elements, and the odd-numbered subtraction capacitive elements according to an odd-numbered clock of the first clock signal on both sides of the differential structure of the second integrator; and
integrate an electric charge sampled at the sampling capacitive elements, the addition capacitive elements, and the even-numbered subtraction capacitive elements according to an even-numbered clock of the first clock signal on both sides of the differential structure of the second integrator.

2. A battery impedance measurement device comprising:
the delta-sigma analog-to-digital converter according to claim 1, wherein
the delta-sigma analog-to-digital converter is configured to:
measure a terminal voltage of a secondary battery and a current flowing through the secondary battery; and
measure an impedance of the secondary battery based on the terminal voltage and the current that are measured by the delta-sigma analog-to-digital converter.
